(19) United States
(12) Patent Application Publication
(10) Pub. No.: US 2007/0054447 A1
(43) Pub. Date: Mar. 8, 2007

(54) Multistep etching method

(76) Inventors: Hsin Tai, Taipei City (TW); Chung-Ju Lee, Hsinchu Hsien (TW); Chih-Ning Wu, Hsinchu (TW)

Correspondence Address: J C PATENTS, INC., 4 VENTURE, SUITE 250, IRVINE, CA, 92618, US

(21) Appl. No.: 11/221,487

(22) Filed: Sep. 7, 2005

(51) Int. Cl. H01L 21/8234; H01L 21/302; H01L 21/3205; H01L 21/336

(52) U.S. Cl. 438/197; 438/300; 438/301; 438/733; 438/595

(57) ABSTRACT

A multi-step etching method is provided. First, a substrate including a gate over the substrate and a spacer over the gate is provided. Then, an anisotropic etching step is performed for etching a first region and a second region in the substrate at two sides of the gate. Thereafter, an isotropic etching step is performed for etching a first external region under the spacer and adjacent to the first region, and etching a second external region under the spacer and adjacent to the second region. Then, a filling step is performed for filling a material into the first region, the first external region, the second region and the second external region.

### BACKGROUND OF THE INVENTION

1. Field of the Invention

The present invention is generally related to a multi-step etching method. More particularly, the present invention relates to a multi-step etching method comprising an isotropic etching step and an anisotropic etching step for increasing the electron mobility in the channel region.

2. Description of Related Art

Conventionally, the basic structure of a metal oxide semiconductor (MOS) transistor has been broadly adopted in a variety of semiconductor devices such as memory device, image sensor, or liquid crystal display (LCD) panel. As the development of the semiconductor technology advances to increase the integration of the semiconductor devices, the line width of the semiconductor device must be reduced. However, a variety of problems arises as the size of MOS structure is reduced.

FIG. 1 is a schematic cross-sectional view illustrating a structure of a conventional MOS transistor. Referring to FIG. 1, the conventional MOS transistor 100 includes a substrate 102, an oxide layer 104, a gate 106, a source 108 and a drain 110. For an N-type MOS (NMOS) transistor, the substrate 102 includes a P-type substrate and the source 108 and the drain 110 are doped with N-type dopants. Alternatively, for a P-type MOS (PMOS) transistor, the substrate 102 includes an N-type substrate and the source 108 and the drain 110 are doped with P-type dopants. In general, the source 108 and the drain 110 are doped by a thermal diffusion method or an ion implantation method. The oxide layer 104 includes such as silicon oxide SiO₂, and the gate 106 includes polysilicon. The region under the oxide layer 104 and between the source 108 and the drain 110 is represented as a channel region 112, wherein a channel length L1 represents a width of the channel region 112 between the source 108 and the drain 110.

As the line width of the conventional MOS transistor 100 is reduced, the channel length L1 is also correspondingly reduced leading to a short channel effect due to reduction in the threshold voltage Vt and increase in the sub-threshold current. In addition, the reduction of channel length L1 also leads to a generation of the hot electron effect due to the increase in the electric field between the source 108 and the drain 110. Therefore, the number of the carriers in the channel region 112 near the drain 110 is increased, and thus an electrical breakdown effect may be generated in the MOS transistor 100. Thus, the channel length L1, in general, has to be sufficiently long to prevent a punch through effect. Accordingly, as the size of the MOS transistor 100 is minimized, the conventional design thereof is not applicable.

Conventionally, to resolve the problem described, a lightly doped drain (LDD) method is performed on the MOS transistor. FIG. 2 is a schematic cross-sectional view illustrating a structure of a conventional MOS transistor having a lightly doped drain (LDD) structure. Referring to FIG. 2, except for the basic structure of the 1 MOS transistor 100 illustrated in FIG. 1, the MOS transistor 200 further includes a lightly doped source region 202 and a lightly doped drain region 204. The doping area and dopant concentration of the lightly doped source region 202 and a lightly doped drain region 204 are smaller than that of the source 108 and the drain 110. Therefore, the hot electron effect due to increase in the electric field between the source 108 and the drain 110 is reduced.

However, a MOS transistor having lightly doped drain (LDD) structure has the following disadvantages. First, the series resistance between the source and the drain is increased due to the dopant concentration of the LDD region is lower. Therefore, the electron mobility during the channel region is reduced, and thus the operation speed of the semiconductor structure including the MOS transistor is also reduced. In addition, the power consumption of the MOS transistor is also increased. Accordingly, a novel MOS transistor and a manufacturing method thereof are quite desirable.

### SUMMARY OF THE INVENTION

Accordingly, the present invention is directed to a multi-step etching method comprising an isotropic etching step and an anisotropic etching step for increasing the electron mobility in the channel region. Therefore, the series resistance between the source and the drain and the power consumption are also reduced drastically.

In addition, the present invention is directed to a multi-step etching method comprising an isotropic etching step and an anisotropic etching step for reducing the generation of the abnormal material layer along the sidewall of the spacer. Thus, the short between the abnormal material layer and the source or drain may be avoided.

In accordance with one embodiment of the present invention, a multi-step etching method is provided. First, a substrate including a gate over a substrate and a spacer over the gate is provided. Then, an anisotropic etching step is performed for etching a first region and a second region in the substrate at two sides of the gate. Thereafter, an isotropic etching step is performed for etching a first external region under the spacer and adjacent to the first region, and etching a second external region under the spacer and adjacent to the second region. Then, a filling step is performed for filling a material into the first region, the first external region, the second region and the second external region.

In one embodiment of the present invention, during the step of providing the substrate, the multi-step etching method further comprises performing a lightly doped drain (LDD) step in a portion of the substrate under the two edges of the gate.

In one embodiment of the present invention, the material comprises epi-silicon (epi-Si), epi-silicon germanium (epi-SiGe) or epi-silicon carbide (epi-SiC).

In one embodiment of the present invention, the anisotropic etching step or the isotropic etching step comprise a dry etching step. In addition, the isotropic etching step comprises a chemical downstream etching method using a remote microwave plasma.

In one embodiment of the present invention, the material is substantially coplanar to a surface of the substrate.

In one embodiment of the present invention, a depth of the first region or the second region perpendicular to a surface of the substrate is in a range of about 40 nm to about 100 nm. In addition, a lateral recess of the first external region or the second external region parallel to a surface of the substrate is in a range of about 17 nm to about 35 nm.

In one embodiment of the present invention, a material of the gate comprises a polysilicon.

In one embodiment of the present invention, the spacer comprises a silicon oxide layer or a silicon nitride layer. In addition, the spacer comprises a silicon oxide layer/silicon nitride layer/silicon oxide layer.

In accordance with another embodiment of the present invention, a multi-step etching method is provided. First, a substrate including a gate over the substrate is provided. Then, a lightly doped drain (LDD) step is performed in a portion of the substrate under two edges of the gate. Thereafter, an anisotropic etching step is performed for etching a first region and a second region in the substrate at two sides of the gate. Then, an isotropic etching step is performed for etching a first external region under the spacer and adjacent to the first region, and etching a second external region under the spacer and adjacent to the second region. Thereafter, a filling step is performed for filling a material into the first region, the first external region, the second region and the second external region.

In one embodiment of the present invention, after the step of performing the LDD step, the multi-step etching method further comprising forming a spacer over the gate.

In one embodiment of the present invention, the spacer comprises a silicon oxide layer or a silicon nitride layer. In addition, the spacer comprises a silicon oxide layer/silicon nitride layer/silicon oxide layer.

In one embodiment of the present invention, the material comprises epi-silicon (epi-Si), epi-silicon germanium (epi-SiGe) or epi-silicon carbide (epi-SiC).

In one embodiment of the present invention, the anisotropic etching step or the isotropic etching step comprises a dry etching step. In one embodiment of the present invention, the isotropic etching step comprises a chemical downstream etching method using a remote microwave plasma.

In one embodiment of the present invention, a depth of the first region or the second region perpendicular to a surface of the substrate is in a range of about 5 nm to about 30 nm. In addition, a lateral recess of the first external region or the second external region parallel to a surface of the substrate is in a range of about 5 nm to about 35 nm.

In one embodiment of the present invention, a material of the gate comprises a polysilicon.

In one embodiment of the present invention, the material that fills the first region, the first external region, the second region and the second external region is protruded above a surface of the substrate.

Accordingly, in the present invention, a multi-step etching method (e.g., including an isotropic etching step and an anisotropic etching step) is provided. Therefore, the generation of an abnormal material layer along the sidewall of the spacer may be prevented. Thus, the short between the abnormal material layer and the source or drain may be avoided. In addition, the electron mobility in the channel region is enhanced. Therefore, the series resistance between the source and the drain and the power consumption are also reduced drastically.

One or part or all of these and other features and advantages of the present invention will become readily apparent to those skilled in this art from the following description wherein there is shown and described a preferred embodiment of this invention, simply by way of illustration of one of the modes best suited to carry out the invention. As it will be realized, the invention is capable of different embodiments, and its several details are capable of modifications in various, obvious aspects all without departing from the invention. Accordingly, the drawings and descriptions will be regarded as illustrative in nature and not as restrictive.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a structure of a conventional MOS transistor.

FIG. 2 is a schematic cross-sectional view of a structure of a conventional MOS transistor having a lightly doped drain (LDD) structure.

FIG. 3A to FIG. 3D are schematic cross-sectional views of a semiconductor structure illustrating a fabrication process of the semiconductor structure according to one embodiment of the present invention.

FIG. 4A to FIG. 4D are schematic cross-sectional views of a semiconductor structure illustrating a fabrication process flow of the semiconductor structure according to another embodiment of the present invention.

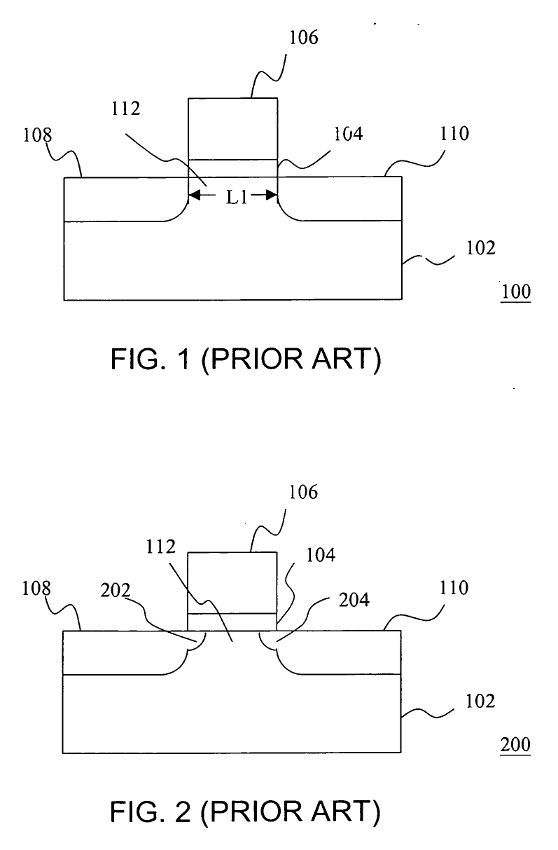

### DESCRIPTION OF THE EMBODIMENTS

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout.

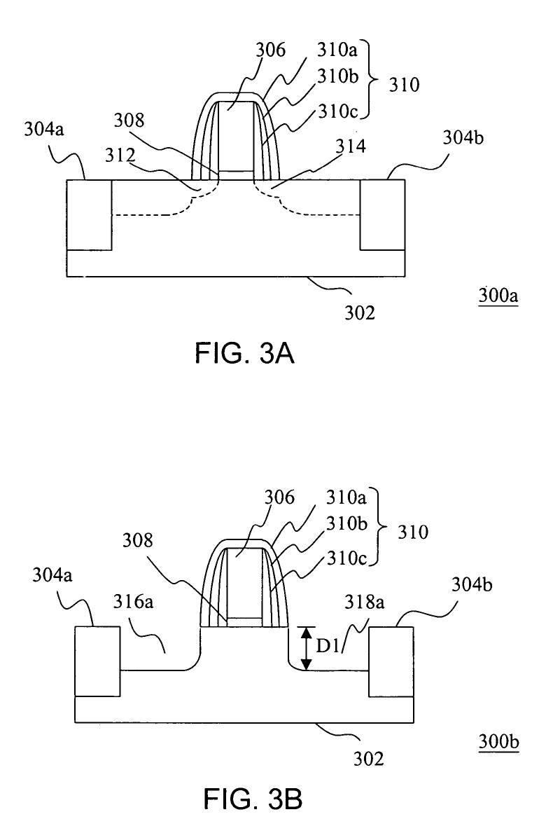

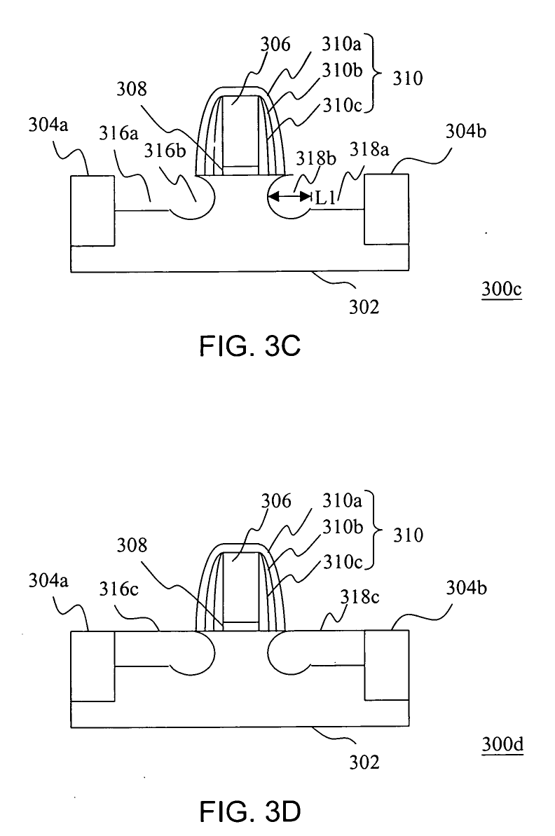

FIG. 3A to FIG. 3D are schematic cross-sectional views of a semiconductor structure illustrating a fabrication process of the semiconductor structure according to one embodiment of the present invention. Referring to FIG. 3A, a semiconductor structure 300a may be formed by, for example but not limited to, the following steps. First, a substrate 302 is provided. The substrate 302 comprises, for example but not limited to, a silicon substrate. In one embodiment of the present invention, isolation structures 304a and 304b may also be formed for isolating each semiconductor structure. The isolation structures 304a and 304b may be, for example but not limited to, a shallow trench isolation (STI) structure. Thereafter, a gate 306 is formed over the substrate 302. The material of the gate 306 comprises, for example but not limited to, a polysilicon. In one embodiment of the present invention, a thin layer 308 may further be formed between the gate 306 and the substrate 302. The material of the thin layer 308 comprises, for example but not limited to, silicon oxide.

Moreover, a spacer 310 may also be formed over the gate 306. The spacer 310 may comprise a single layer, or a multiple layer structure including spacers 310a, 310b and 310c. In FIG. 3A, three spacers are illustrated as an exemplary example. However, it is noted that, in the present invention, the spacer may comprise one or more layers. The material of the spacer 310 includes, for example but not limited to, silicon oxide or silicon nitride, wherein a thickness of the spacer 310 may be, for example, in a range of about 2 nm to about 60 nm. The spacers 310a/310b/310c comprise, for example but not limited to, silicon oxide/silicon nitride/silicon oxide layers, wherein a thickness of the spacers 310a/310b/310c may be, for example, about 2 nm to about 10 nm for the spacer 310a, about 10 nm to about 25 nm for the spacer 310b, and about 10 nm to about 25 nm for the spacer 310c.

Referring to FIG. 3A, in one embodiment of the present invention, a lightly doped drain (LDD) step may be optionally performed on regions 312 and 314 in the substrate 302 under two edges of the gate 306. The regions 312 and 314 may be doped with, for example but not limited to, N-type dopant or p-type dopant.

Referring to FIG. 3B, an anisotropic etching step is performed to the semiconductor structure 300a for etching a region 316a and a region 318a in the substrate 302 at two sides of the gate 306. The anisotropic etching step is mainly performed for etching the region 316a and the region 318a in a direction perpendicular to the surface of the substrate 302. Therefore, a depth of the region 316a or the region 318a (illustrated as the length of the arrow D1) may be, for example but not limited to, in a range of about 40 nm to about 100 nm. In one embodiment of the present invention, the anisotropic etching step comprises, for example but not limited to, a dry etching method comprising, for example, a plasma etching method, or a wet anisotropic etching method. Accordingly, a semiconductor structure 300b as illustrated in FIG. 3B is formed after the anisotropic step.

Thereafter, referring to FIG. 3C, an isotropic etching step is performed to the semiconductor structure 300b for etching an external region 316b and an external region 318b in the substrate 302 at two sides of the gate 306. The isotropic etching step is mainly performed for etching the external region 316b and the external region 318b in a direction parallel to the surface of the substrate 302. Therefore, a lateral recess of the external region 316b or the external region 318b (illustrated as the length of the arrow L) may be, for example but not limited to, in a range of about 17 nm to about 35 nm. In one embodiment of the present invention, the isotropic etching step comprises, for example but not limited to, a dry etching method comprising, for example, a chemical downstream etching method using a remote microwave plasma, or a wet anisotropic etching method. Accordingly, a semiconductor structure 300c as illustrated in FIG. 3C is formed after the isotropic etching step.

Thereafter, referring to FIG. 3D, a filling step is performed for filling a material into the region 316a, the external region 316b, the region 318a and the external region 318b. Therefore, a source region 316c and a drain region 318c are formed. In one embodiment of the present invention, the material comprises, for example but not limited to, epi-silicon (epi-Si), epi-silicon germanium (epi-SiGe) or epi-silicon carbide (epi-SiC). In one embodiment of the present invention, the surface of the source region 316c and the drain region 318c may be substantially coplanar to the surface of the substrate 302.

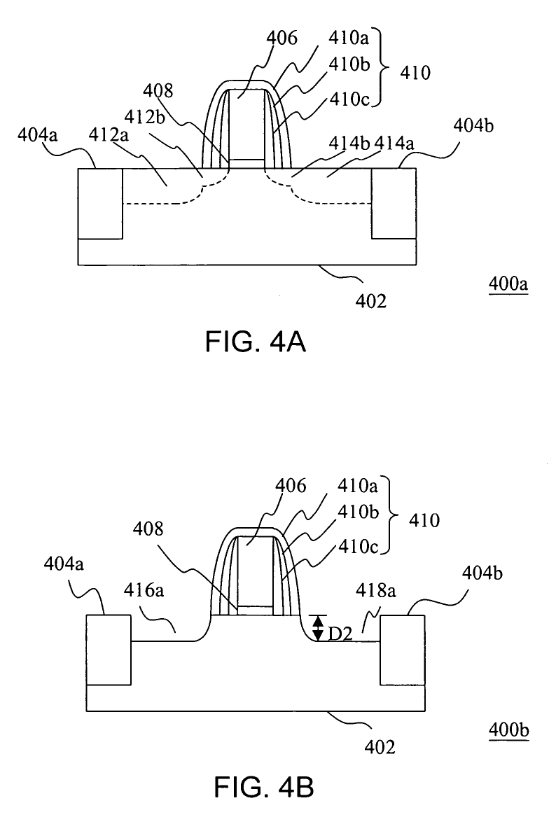

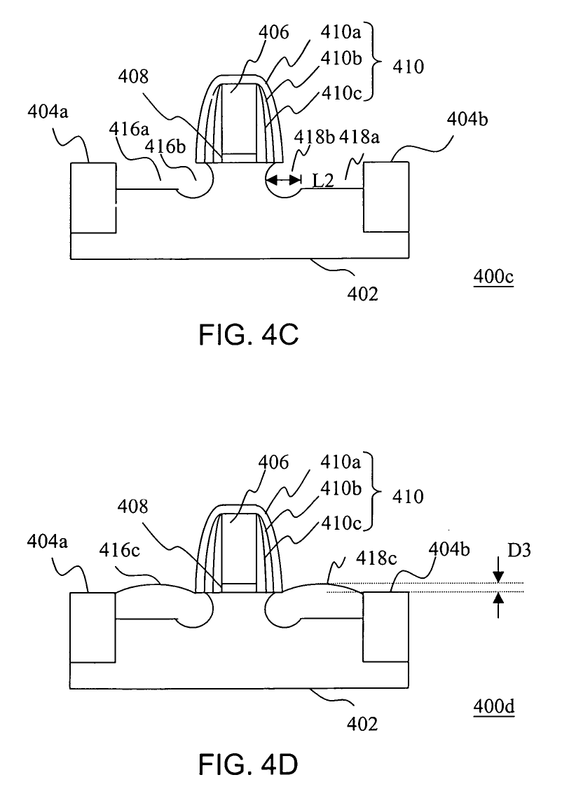

FIG. 4A to FIG. 4D are schematic cross-sectional views of a semiconductor structure illustrating a fabrication process of the semiconductor structure according to another embodiment of the present invention. Referring to FIG. 4A, a semiconductor structure 400a may be formed by, for example but not limited to, the following steps. First, a substrate 402 is provided. The substrate 402 comprises, for example but not limited to, a silicon substrate. In one embodiment of the present invention, the isolation structures 404a and 404b may also be formed for isolating each semiconductor structure. The isolation structures 404a and 404b may be, for example but mot limited to, a shallow trench isolation (STI) structure. Thereafter, a gate 406 is formed over the substrate 402. The material of the gate 406 comprises, for example but not limited to, polysilicon. In one embodiment of the present invention, a thin layer 408 may further be formed between the gate 406 and the substrate 402. The material of the thin layer 408 comprises, for example but not limited to, silicon oxide.

Referring to FIG. 4A, regions 412a and 414a may be, for example but not limited to, doped with N-type dopant or p-type dopant. In addition, a lightly doped drain (LDD) step may be performed on regions 412b and 414b in the substrate 402 under two edges of the gate 406. The regions 412b and 414b may also be lightly doped with, for example but not limited to, N-type dopant or p-type dopant. The doping area and the dopant concentration of the lightly doped regions 412b and 414b are smaller than that of the regions 412a and 414a.

Furthermore, in one embodiment of the present invention, a spacer 410 may be optionally formed over the gate 406. The spacer 410 may comprise a single layer, or a multiple layer structure including spacers 410a, 410b and 410c. In FIG. 4A, three spacers are illustrated as an exemplary example. However, it is noted that, in the present invention, the spacer may comprise one or more layers. The material of the spacer 410 comprises, for example but not limited to, a silicon oxide or a silicon nitride, wherein a thickness of the spacer 410 may be, for example, in a range of about 2 nm to about 60 nm. The spacers 410a/410b/410c comprise, for example but not limited to, silicon oxide/silicon nitride/silicon oxide layers, wherein a thickness of the spacers 410a/410b/410c may be, for example, about 2 nm to about 10 nm for the spacer 310a, about 10 nm to about 25 nm for the spacer 310b, and about 10 nm to about 25 nm for the spacer 310c.

Referring to FIG. 4B, an anisotropic etching step is performed to the semiconductor structure 400a for etching a region 416a and a region 418a in the substrate 402 at two sides of the gate 406. The anisotropic etching step is mainly performed for etching the region 416a and the region 418a in a direction perpendicular to the surface of the substrate 402. Therefore, a depth of the region 416a or the region 418a (illustrated as the length of the arrow D2) may be, for example but not limited to, in a range of about 5 nm to about 30 nm. In one embodiment of the present invention, the anisotropic etching step comprises, for example but not limited to, a dry etching method comprising, for example, a plasma etching method or a wet anisotropic etching method. Accordingly, a semiconductor structure 400b as illustrated in FIG. 4B is formed after the anisotropic etching step.

Thereafter, referring to FIG. 4C, an isotropic etching step is performed to the semiconductor structure 400b for etching an external region 416b and an external region 418b in the substrate 402 at two sides of the gate 406. The isotropic etching step is mainly performed for etching the external region 416b and the external region 418b in a direction parallel to the surface of the substrate 402. Therefore, a lateral recess of the external region 416b or the external region 418b (illustrated as the length of the arrow L2) may be, for example but not limited to, in a range of about 5 nm to about 35 nm. In one embodiment of the present invention, the isotropic etching step comprises, for example but not limited to, a dry etching method comprising, for example, a chemical downstream etching method using a remote microwave plasma, or a wet anisotropic etching method. Accordingly, a semiconductor structure 400c as illustrated in FIG. 4C is formed after the isotropic etching step.

Thereafter, referring to FIG. 4D, a filling step is performed for filling a material into the region 416a, the external region 416b, the region 418a and the external region 418b. Therefore, a source region 416c and a drain region 418c are formed. In one embodiment of the present invention, the material comprises, for example but not limited to, epi-silicon (epi-Si), epi-silicon germanium (epi-SiGe) or epi-silicon carbide (epi-SiC). In one embodiment of the present invention, the surface of the source region 416c and the drain region 418c may be protruded above the surface of the substrate 402. The distance between the highest surface of the source region 416c (or the drain region 418c) and the surface of the substrate may be, for example but not limited to, about 5 nm to 15 nm.

In summary, in the embodiments of the present invention described above, two etching steps (including an anisotropic etching step and an isotropic step) is performed to etch the substrate. It should be noted that, if only one etching step (e.g., the anisotropic etching step) is performed, an abnormal material layer may be produced along the sidewall of the spacer. Therefore, the abnormal material layer may be short with the source region or the drain region. Accordingly, in the present invention, an isotropic step is performed after the anisotropic etching step. Therefore, the generation of the abnormal material layer may be prevented.

In one embodiment of the present invention, with the aid of the isotropic etching step and the anisotropic etching step, after the filling step, the electron mobility in the channel region between the source and the drain are enhanced for, for example but not limited to, about 10% to about 25%. In the present invention, the electron mobility in the channel region is enhanced since the material that fills the source region and the drain region is longitudinal uniaxial compressively strained. Therefore, in the present invention, the series resistance between the source and the drain, the electron mobility in the channel region, and the power consumption are reduced drastically.

Accordingly, in the present invention, a multi-step etching method (e.g., including an isotropic etching step and an anisotropic etching step) is provided. Therefore, the generation of an abnormal material layer along the sidewall of the spacer may be prevented. Thus, a short between the abnormal material layer and the source or drain may be avoided. In addition, the electron mobility in the channel region is enhanced. Therefore, the series resistance between the source and the drain and the power consumption are also reduced drastically.

The foregoing description of the preferred embodiment of the present invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A multi-step etching method, comprising:
providing a substrate, wherein a gate is formed over the substrate, and a spacer is formed over the gate;
performing an anisotropic etch step, for etching a first region and a second region in the substrate at two sides of the gate;
performing an isotropic etch step, for etching a first external region under the spacer and adjacent to the first region, and etching a second external region under the spacer and adjacent to the second region; and
performing a filling step, for filling a material into the first region, the first external region, the second region and the second external region.

2. The multi-step etch method of claim 1, wherein during the step of providing the substrate, further comprising:
performing a lightly doped drain (LDD) step in a portion of the substrate under two edges of the gate.

3. The multi-step etching method of claim 1, wherein the material comprises epi-silicon (epi-Si).

4. The multi-step etching method of claim 1, wherein the material is an epi-silicon germanium (epi-SiGe) layer or an epi-silicon carbide (epi-SiC) layer.

5. The multi-step etching method of claim 1, wherein the anisotropic etching step or the isotropic etching step comprises a dry etching step.

6. The multi-step etching method of claim 1, wherein the isotropic etching step comprises a chemical downstream etching method using a remote microwave plasma.

7. The multi-step etching method of claim 1, wherein the material is substantially coplanar to a surface of the substrate.

8. The multi-step etching method of claim 1, wherein a depth of the first region or the second region perpendicular to a surface of the substrate is in a range of about 40 nm to about 100 nm.

9. The multi-step etching method of claim 1, wherein a lateral recess of the first external region or the second external region parallel to a surface of the substrate is in a range of about 17 nm to about 35 nm.

10. The multi-step etching method of claim 1, wherein a material of the gate comprises a polysilicon.

11. The multi-step etching method of claim 1, wherein the spacer is a silicon oxide layer or a silicon nitride layer.

12. The multi-step etching method of claim 1, wherein the spacer comprises a silicon oxide layer/silicon nitride layer/silicon oxide layer.

13. A multi-step etching method, comprising:
providing a substrate, wherein a gate is formed over the substrate;
performing a lightly doped drain (LDD) step in a portion of the substrate under two edges of the gate.
performing an anisotropic etching step, for etching a first region and a second region in the substrate at two sides of the gate;
performing an isotropic etching step, for etching a first external region under the spacer and adjacent to the first region, and etching a second external region under the spacer and adjacent to the second region; and
performing a filling step, for filling a material into the first region, the first external region, the second region and the second external region.

14. The multi-step etching method of claim 13, wherein after the step of performing the LDD step, further comprising:
forming a spacer over the gate.

15. The multi-step etching method of claim 14, wherein the spacer is a silicon oxide layer or a silicon nitride layer.

16. The multi-step etching method of claim 14, wherein the spacer comprises a silicon oxide layer/silicon nitride layer/silicon oxide layer.

17. The multi-step etching method of claim 13, wherein the material comprises epi-silicon (epi-Si).

18. The multi-step etching method of claim 13, wherein the material is an epi-silicon germanium (epi-SiGe) layer or an epi-silicon carbide (epi-SiC) layer.

19. The multi-step etching method of claim 13, wherein the anisotropic etching step or the isotropic etching step comprises a dry etching step.

20. The multi-step etching method of claim 13, wherein the isotropic etching step comprises a chemical downstream etching method using a remote microwave plasma.

21. The multi-step etching method of claim 13, wherein a depth of the first region or the second region perpendicular to a surface of the substrate is in a range of about 5 nm to about 30 nm.

22. The multi-step etching method of claim 13, wherein a lateral recess of the first external region or the second external region parallel to a surface of the substrate is in a range of about 5 nm to about 35 nm.

23. The multi-step etching method of claim 13, wherein a material of the gate comprises a polysilicon.

24. The multi-step etching method of claim 13, wherein the material is protruded above a surface of the substrate.
